(19) United States
(12) Patent Application Publication
(10) Pub. No.: US 2016/0370415 A1
(43) Pub. Date: Dec. 22, 2016

(54) SPARK TESTER APPARATUS AND METHOD

(71) Applicants: David L. Carroll, Branford, CT (US); Theodore P. Lane, Clinton, CT (US); Richard J. Langley, Old Lyme, CT (US); Thomas L. Listorti, Old Saybrook, CT (US)

(72) Inventors: David L. Carroll, Branford, CT (US); Theodore P. Lane, Clinton, CT (US); Richard J. Langley, Old Lyme, CT (US); Thomas L. Listorti, Old Saybrook, CT (US)

(73) Assignee: CLINTON INSTRUMENT COMPANY, Clinton, CT (US)

(21) Appl. No.: 14/740,722

(22) Filed: Jun. 16, 2015

(51) Int. Cl. G01R 31/02; G01R 31/12

(52) U.S. Cl. CPC G01R 31/022; G01R 31/1272

(57) ABSTRACT

A spark tester electrode includes a first bracket that supports a first plurality of filaments and a second bracket that supports a second plurality of filaments. The first and second brackets are mutually disposed at angles toward each other, such that the first plurality of filaments that are supported from the first bracket intermingle with the second plurality of filaments that are supported from the second bracket.

### BACKGROUND

Technical Field

The invention relates to manufacture of insulated electrical cables. More particularly, the invention relates to apparatus and methods for quality assurance of the cable insulation.

Discussion of Art

A key purpose for insulating an electrical cable is to mitigate hazards of electrical shock or ignition that an energized cable presents to nearby personnel and structures. Another purpose of cable insulation is to avert abrasive damage to the cable. Instead, the insulation will be abraded.

Sometimes, abrasions or imperfections in coating processes can damage the insulation on a cable. Beyond compromising the ability of the insulation to protect the cable, even minor defects (pinholes or thinned spots) can render the insulation ineffectual to protect personnel and structures from electrical current carried by the cable when energized. Larger defects (bare metal or gross bare wire conditions) can present severe risks of electrocution or combustion.

Accordingly, cable manufacturers presently use various modes of cable insulation inspection. One mode of inspection, in long use, which has been approved by the Underwriters Laboratories, is known as “spark testing.” In spark testing, an insulated cable is run lengthwise through an electrode that is charged to a relatively high voltage (on the order of a few thousand to several thousand volts DC or AC). At least one end of the insulated cable is grounded. Voltage at the electrode is monitored. In case the electrode voltage dips below its controlled value, this dip is understood to indicate an insulation defect that is permitting the electrode voltage to at least partially discharge through the insulation and cable to ground. Because the cable is being run lengthwise through the electrode, the voltage dip can be correlated to a location along the cable by rote calculations.

In order to avoid missing an insulation fault, it is important to assure continuous electrical contact from the electrode to the cable. For this purpose, filament-type electrodes (e.g. brush or chain electrodes) are known. Various modes have been considered for inserting the cable through the filament electrodes. Generally, the cable is threaded through the electrode sideways, i.e., transverse the length of the cable. However, sideways insertion often results in an uneven distribution of beads during testing, which can result in a gap in the filaments, adjacent to the surface of the test cable. This gap counters the overall purpose of the filament electrode, in that the gap reduces uniformity and consistency of electrical contact from the filaments to the insulated cable.

An improvement to this type of electrode is to split the electrode, along the vertical axis of the test cable, and to hinge the electrode halves, and to provide a latch for closing the electrode in use. Thus when the cable is inserted into the electrode, and the electrode closed around the cable, it is then centered axially, eliminating gapping adjacent to the test cable.

However, methods currently in use for fixing the filament elements to the hinged electrode troughs allow for small air gaps between the filament sections at the cable centerline. This remains problematic in the testing of small cables, with diameters less than the resultant air gap.

### SUMMARY OF INVENTION

In consideration of the above, embodiments of the invention provide a filament-type electrode in which uniformity and consistency of electrical contact is increased as further discussed below. Aspects of the invention provide for spark testing a moving cable by closing around the cable a split trough type electrode; energizing the electrode; and monitoring a voltage at the electrode, wherein the electrode includes first and second pluralities of filaments that are intermingled with each other. A benefit of this new electrode is that it provides more intimate contact between the filaments and the wire under test, which enables use of lower test voltages for smaller wires. Another benefit is that the new electrode provides for reliable actual contact between the filaments and the wire under test, a novel condition that can support sophisticated insulation fault typing, as disclosed and claimed in co-pending and commonly owned application [Atty Dkt. 0319-0054] “Apparatus and Method for Spark Fault Detection and Typing.”

Thus, embodiments of the invention provide a spark tester electrode article, which includes a first bracket that supports a first plurality of filaments and a second bracket that supports a second plurality of filaments. The first and second brackets are mutually disposed at angles toward each other, such that the first plurality of filaments that are supported from the first bracket intermingle with the second plurality of filaments that are supported from the second bracket.

Other embodiments provide an improved high-voltage spark tester apparatus, which includes an electrical power supply; a voltage monitoring circuit; and an electrode electrically connected with the electrical power supply and with the voltage monitoring circuit. The electrode includes first and second brackets that support respective first and second pluralities of filaments, and the first and second brackets are mutually disposed at angles toward each other, such that the first plurality of filaments that are supported from the first bracket intermingle with the second plurality of filaments that are supported from the second bracket.

The varied exemplary embodiments of the invention, as briefly described above, are illustrated by certain of the following figures.

### BRIEF DESCRIPTION OF DRAWINGS

FIG. 1 depicts schematically an improved spark tester apparatus with an electrode according to an embodiment of the invention.

FIG. 2 depicts in perspective view the apparatus of FIG. 1.

FIG. 3 depicts schematically the apparatus of FIGS. 1 and 2 with the electrode in an opened position.

FIG. 4 depicts schematically a second type of electrode according to embodiments of the invention.

FIG. 5 depicts schematically a third type of electrode according to embodiments of the invention.

### DETAILED DESCRIPTION

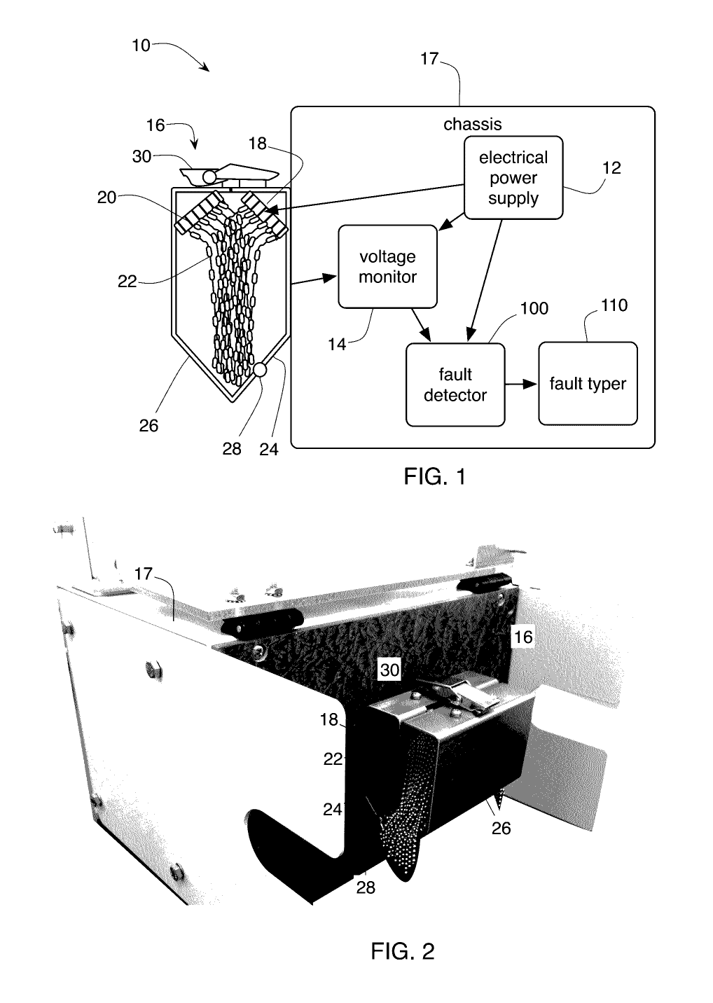

Referring to FIG. 1, an exemplary embodiment provides an improved High-voltage spark tester apparatus 10, which includes an electrical power supply 12, a voltage monitoring circuit 14, and an electrode 16 that is electrically connected with both the electrical power supply and the voltage monitoring circuit. The electrical power supply 12 and the voltage monitoring circuit 14 are housed within a chassis 17, to which the electrode 16 is mounted. While in most applications the electrode will be directly mounted to the chassis as shown, it is possible that the electrode may be remotely mounted and cable-connected to the chassis. Although not specifically shown, such an embodiment may be implemented by the skilled worker without further instruction.

In use of the apparatus 10, the electrical power supply 12 would energize the electrode 16. Typically, the electrical power supply 12 would provide high frequency, high voltage current (e.g., up to 15 kV at a nominal frequency of 3000 Hz) under a current limit of significantly less than 1 A (e.g., less than about 400 mA, or even less than about 4 mA). In case direct current would be used, then a typical embodiment of the electrical power supply 12 could supply current limited voltage within ranges of 0-1 kV, 0-10 kV, 0-20 kV, or 0-50 kV. Generally, the electrical power supply 12 would be designed to connect with AC mains 0-30 kV at either 50 Hz or 60 Hz power line frequency.

In operation, an insulated cable would be passed through the electrode transverse the drawing view, i.e. in a direction into or out of the view plane. The insulated cable would be grounded at least at one end, either directly or through a capacitor, and the electrode voltage would be monitored by the voltage monitoring circuit 14, so that faults in the cable insulation could be detected by the fault detection circuit 100 as dips of the electrode voltage toward ground.

In order to obtain direct electrical contact with the insulated cable, the electrode 16 includes a first mounting bracket 18 and a second mounting bracket 20, each of which supports a respective first or second plurality of filaments 22 for the purpose of establishing substantially continuous electrical contact between the electrode and an insulated cable passing through the electrode. The filaments 22 may be bead chains, wire bristles, or similar flexible and conductive members that may drape or elastically bend against the insulated cable that passes among the filaments.

The first and second brackets 18, 20 are mutually disposed at angles toward each other, such that the first plurality of filaments 22 that are supported from the first bracket intermingle with the second plurality of filaments 22 that are supported from the second bracket. This intermingling of the filaments enhances their mutual electrical contact as well as their electrical contact with the aforesaid insulated cable as the cable moves along its length traversing the filaments. The enhanced electrical contact provides for continuity and consistency of spark fault detection, which is a purpose of the electrode 16.

As shown in FIGS. 1 through 3, the filaments 22 of the first plurality and the filaments 22 of the second plurality are bead chains. However, as shown in FIGS. 4 and 5 the filaments 22 of the first or upper plurality may be bead chains whereas the filaments 22 of the second or lower plurality may be wire bristles. Alternatively, both sets of filaments 22 may be wire bristles. Further, in certain embodiments tandem filament pairs may be provided, i.e. bead chains followed by filaments further along the motion of the cable. Although not shown in the drawings, an ordinary skilled worker can implement such embodiments without further guidance.

Depending on factors including the stiffness of the filaments 22, the first and second brackets 18, 20 may be mutually angled such that each plurality of filaments protrudes at an angle downward from a horizontal plane and toward the other bracket. Also, the filaments supported by one or the other or both brackets may bend downward away from the other bracket throughout their lengths.

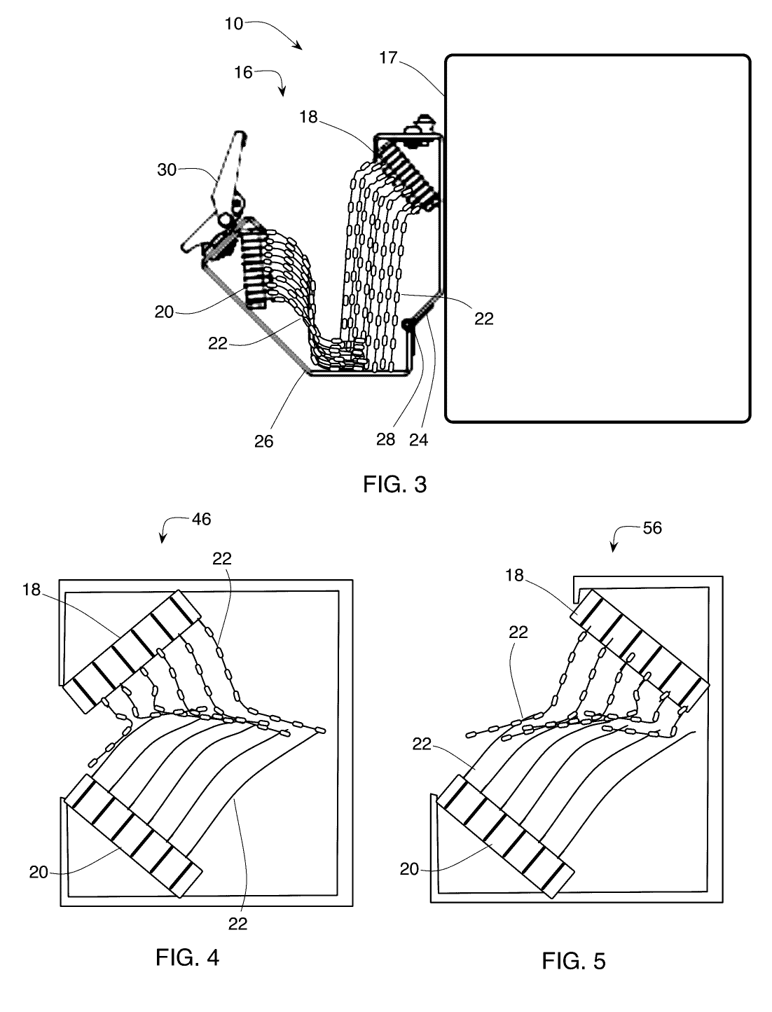

In the embodiments shown in FIGS. 1-3, the electrode 16 is provided as a split trough type electrode that has a first portion 24 in which the first bracket 18 is mounted. This first portion 24 of the electrode 16 is mounted rigidly to the chassis 17. The split trough type electrode 16 also has a second portion 26, which is hingedly connected with the first portion 24. The first and second portions 26, 28 are joined at a hinge 28, which is provided to allow the second portion 26 to open away and downward from the first portion 24, as shown in FIG. 3, thus providing a gap for inserting a cable transverse the filaments 22. Once the cable has been inserted, then the electrode portions 24, 26 are closed around the cable such that the first and second brackets 18, 20 assume their mutually angled dispositions to face each other across a generally vertical plane when the first and second portions of the electrode are in a mutually adjacent closed position. A latch 30 is also provided, generally opposite the hinge 28, for fastening the electrode in its closed configuration.

Alternatively, in another embodiment as shown in FIG. 4, the first and second brackets 18, 20 may be disposed within an open jaw electrode 46 at mutual angles to face each other across a horizontal plane, thereby defining a horizontal opening for admittance of a cable among the first and second pluralities of filaments 22. In such embodiments it will be preferred to have the filaments 22 of the second bracket 20, i.e. the bottom or lower bracket, be wire bristles or similar upstanding members so as to provide for intermingling of first and second pluralities of filaments 22.

In yet another embodiment as shown in FIG. 5, a second open jaw electrode 56 may have a similar arrangement of first and second brackets 18, 20 that face each other across a horizontal plane. However, in this embodiments the brackets are offset horizontally, thus providing a wider opening (relative to the embodiment of FIG. 4) for inserting a cable transversely between the brackets.

Referring back to FIG. 1, the spark tester apparatus 10 may also include a fault detector circuit 100 that is electrically connected with the electrode 16, e.g., between the voltage monitoring circuit 14 and a fault typer circuit 110. The fault detector circuit 100, generally, will detect changes in the monitored voltage produced by passage through the electrode 16 of a cable section that has faulty or missing insulation. Typically, the monitored voltage will diminish in amplitude as the faulty or missing insulation permits the electrode field to short to ground. The fault detector circuit 100 is configured to identify voltage fluctuations due to insulation faults. The fault typer circuit 110 is configured to distinguish voltage responses due to various types of insulation fault, e.g. metal contact, bare wire, pinholes, or multiple pinholes.

Although exemplary embodiments of the invention have been described with reference to attached drawings, those skilled in the art nevertheless will apprehend variations in form or detail that are consistent with the scope of the invention as defined by the appended claims.

What is claimed is:

1. An improved high-voltage spark tester apparatus comprising:
an electrical power supply;
a voltage monitoring circuit; and
an electrode electrically connected with the electrical power supply and with the voltage monitoring circuit, wherein said electrode comprises first and second brackets that support respective first and second pluralities of filaments, and the first and second brackets are mutually disposed at angles toward each other, such that the first plurality of filaments that are supported from the first bracket intermingle with the second plurality of filaments that are supported from the second bracket.

2. The apparatus of claim 1 wherein at least some of the filaments are bead chains.

3. The apparatus of claim 1 wherein at least some of the filaments are wire bristles.

4. The apparatus of claim 1 wherein the first plurality of filaments are bead chains.

5. The apparatus of claim 1 wherein the second plurality of filaments are wire bristles.

6. The apparatus of claim 1 further comprising a chassis housing the electrical power supply and the voltage monitoring circuit, with the electrode mounted on the chassis.

7. The apparatus of claim 1 wherein the electrode is a split trough electrode, the first bracket is mounted within a first portion of the electrode, the second bracket is mounted within a second portion of the electrode that is hingedly connected with the first portion of the electrode, and the first and second brackets assume their mutually angled dispositions to face each other across a generally vertical plane when the first and second portions of the electrode are in a mutually adjacent closed position.

8. The apparatus of claim 1 wherein the first plurality of filaments protrude at an angle downward from a horizontal plane and toward the second plurality of filaments when the brackets are in their mutually angled dispositions.

9. The apparatus of claim 1 wherein the first and second brackets are mutually disposed, such that filaments protruding from the first bracket bend downward away from the second bracket along their length.

10. The apparatus of claim 1 wherein the first and second brackets are disposed at mutual angles to face each other across a horizontal plane, thereby defining a horizontal opening for admittance of a cable among the first and second pluralities of filaments.

11. A spark tester electrode article comprising:
a first bracket that supports a first plurality of filaments; and
a second bracket that supports a second plurality of filaments;
wherein the first and second brackets are mutually disposed at angles toward each other, such that the first plurality of filaments that are supported from the first bracket intermingle with the second plurality of filaments that are supported from the second bracket.

12. The article of claim 11 wherein at least some of the filaments are bead chains.

13. The article of claim 11 wherein at least some of the filaments are wire bristles.

14. The article of claim 11 wherein the first plurality of filaments are bead chains.

15. The article of claim 11 wherein the second plurality of filaments are wire bristles.

16. The article of claim 11 wherein the first bracket is mounted within a first portion of the electrode, the second bracket is mounted within a second portion of the electrode that is hingedly connected with the first portion of the electrode, and the first and second brackets assume their mutually angled dispositions to face each other across a plane when the first and second portions of the electrode are in a mutually adjacent closed position.

17. The article of claim 11 wherein the first and second brackets are disposed at mutual angles to face each other across a plane, and are spaced apart to define a horizontal opening for admittance of a cable among the first and second pluralities of filaments.

18. A method for spark testing a moving cable comprising:
closing around the cable a split trough type electrode;
moving the cable lengthwise through the electrode;
energizing the electrode; and
monitoring a voltage at the electrode;
wherein the electrode includes first and second pluralities of filaments that are intermingled with each other.

19. The method of claim 18 further comprising detecting a fault in case the amplitude of voltage at the electrode drops from a first predetermined value toward a second predetermined value.

20. The method of claim 18 further comprising obtaining continuous contact of electrode filaments with the cable periphery.
